(19) United States
(12) Patent Application Publication
(10) Pub. No.: US 2010/0260944 A1
(43) Pub. Date: Oct. 14, 2010

(54) METHOD FOR FORMING SILICON DOTS

(76) Inventors: Atsushi Tomyo, Osaka (JP); Hirokazu Kaki, Kyoto (JP); Eiji Takahashi, Kyoto (JP)

Correspondence Address: Cheng Law Group, PLLC, 1100 17th Street, N.W., Suite 503, Washington, DC, 20036, US

(21) Appl. No.: 12/739,982

(22) PCT Filed: Oct. 14, 2008
(86) PCT No.: PCT/JP2008/068929

§ 371 Date: Jun. 9, 2010

(30) Foreign Application Priority Data
Oct. 30, 2007 (JP) 2007-281722

(51) Int. Cl. C23C 16/505; C23C 16/24

(52) U.S. Cl. 427/539

(57) ABSTRACT

A method for forming silicon dots which can form silicon dots at a relatively low temperature, with good controllability of the particle diameter of silicon dots depending on the particle diameter of silicon dots to be formed.

The method for forming silicon dots comprises producing inductively coupled plasma from a gas for forming silicon dots provided within the plasma producing chamber by applying a high-frequency power to an antenna with reduced inductance placed within the plasma producing chamber to form silicon dots on a substrate S disposed within the chamber in the presence of the inductively coupled plasma. Conditions for a pretreatment of the substrate prior to the formation of silicon dots, the temperature of the substrate in forming silicon dots and the gas pressure in the plasma producing chamber during the formation of silicon dots are controlled depending on the particle diameter of the silicon dots.

### TECHNICAL FIELD

The present invention relates to a method for forming silicon dots of minute sizes, that is, minute particles of silicon crystals having a particle diameter of about 1 nm to 10 nm, that can be used as electronic device materials, light emission materials and others, also known as silicon nanocrystal particles, or silicon nanoparticles.

### BACKGROUND ART

For example, Japanese Unexamined Patent Publication No. 2006-176859 (JP2006-176859, A) describes a method for producing silicon nanocrystal structure, comprising a first step in which silicon nanocrystal particles having a particle diameter of 10 nm or smaller are grown by a thermal CVD method, a second step in which the surfaces of the silicon nanocrystal particles are oxidized or nitrided, a third step in which the silicon nanocrystal particles are subjected to a heat treatment at temperature higher than the growth temperature of the silicon nanocrystal particles, and repeating the first to third steps until a thin film having a predetermined thickness is obtained.

Moreover, a temperature of 500° C. to 600° C. is described as the growth temperature of the silicon nanocrystal particles in the first step, while a temperature of 800° C. to 1100° C. is mentioned as the heat treatment temperature in the third step. The document describes that silicon nanocrystal particles having a particle diameter of 10 nm or smaller can be formed at the growth temperature of the silicon nanocrystal particles of 500° C. to 600° C.

### DISCLOSURE OF THE INVENTION

### Object to be Achieved by the Invention

However, the temperature of a substrate on which silicon dots are to be formed in forming silicon dots is preferably a low temperature. The reason is that the lower the substrate temperature, the lower the heat load of the apparatus for forming silicon dots, whereby the apparatus can be provided economically. Moreover, the range of selection of substrate materials is broadened in terms of heat resistance. Another reason is that agglomeration of silicon dots, which is likely to be caused in the formation of silicon dots at a high temperature and may make controlling of the particle diameter of silicon dots difficult, can be suppressed.

Japanese Unexamined Patent Publication No. 2006-176859 (JP2006-176859, A) also describes that silicon nanocrystal particles having a particle diameter of 10 nm or smaller can be formed at the growth temperature of the silicon nanocrystal particles of 500° C. to 600° C. However, even in a particle diameter range of 10 nm or less, it is preferable, depending on the application of the silicon nanocrystal particles, to reduce the range of the particle diameter of the silicon nanocrystal particles to be formed so that the particle diameter falls within a desired range.

For example, to impart an electron retaining function to silicon dots in forming a memory device using silicon dots, the particle diameter of the silicon dots may be in the range of about 5 nm to 10 nm.

For example, in forming a light-emitting device using silicon dots, it is desirable that the particle diameter of the silicon dots is in the range of about 1 nm to 5 nm.

Accordingly, it is an object of the present invention to provide a method for forming silicon dots which can form silicon dots at a relatively low temperature, with good controllability of the particle diameter of silicon dots depending on the particle diameter of silicon dots to be formed.

### Means for Achieving the Object

According to the research conducted by the inventors of the present invention, high-density plasma containing radical species which serve as a material for silicon dots at a high density can be formed by producing inductively coupled plasma from a gas for forming silicon dots fed into a plasma producing chamber by applying a high-frequency power to an antenna with reduced inductance placed within the chamber, and silicon dots can be formed at a relatively low temperature by forming silicon dots on a substrate in the presence of the high-density plasma.

According to the research conducted by the inventors of the present invention, in general, the lower the temperature of the substrate in forming silicon dots and the higher the gas pressure for forming silicon dots, the smaller the particle diameter of the silicon dots. When the substrate is exposed to plasma prior to the formation of silicon dots as a pretreatment, the particle diameter of the silicon dots is also affected by the pretreatment.

According to the research conducted by the inventors of the present invention,

the pretreatment of the substrate is conducted by exposing the substrate to oxygen plasma;

the temperature of the substrate in forming silicon dots is set at room temperature (about 25° C.) or higher but lower than 250° C.; and the gas pressure in the plasma producing chamber during the formation of silicon dots is set at 2.0 Pa or higher but 6.0 Pa or lower, whereby silicon dots having a particle diameter smaller than 5 nm (e.g., about 1 nm for small-diameter silicon dots) can be formed.

If the time for exposing the substrate to oxygen plasma in the pretreatment during this formation of silicon dots is too short, the effect of conducting the oxygen plasma process is eliminated. On the other hand, if the time is too long, the area of the site on which the silicon dots are formed is extremely reduced, whereby the density of the silicon dots is lowered excessively. Therefore, the range of the time is, for example, 1 second to 60 seconds in general.

When the temperature of the substrate in forming silicon dots is lower than room temperature (about 25° C.), it is difficult for silicon to be crystallized, and it is therefore difficult for the dots themselves to be formed. When the temperature of the substrate is 250° C. or higher, diffusion of radicals of deposition species on the substrate is promoted excessively, and the silicon dots may grow widely in the horizontal direction. Therefore, the temperature may be set to room temperature or higher but lower than 250° C. The temperature of the substrate may be set to 100° C. or higher but lower than 250° C.

When the gas pressure in the plasma producing chamber during the formation of silicon dots is lower than 2.0 Pa, the amount of the radicals of deposition species which reach the substrate is increased, and silicon dots grow larger. When the gas pressure is higher than 6.0 Pa, there is a possibility of powder generation due to the polymerization reaction of the radicals of deposition species in the gas phase. Therefore, the gas pressure may be set to 2.0 Pa or higher but 6.0 Pa or lower.

According to the research conducted by the inventors of the present invention,

the pretreatment of the substrate is conducted by exposing the substrate to hydrogen plasma;

the temperature of the substrate in forming silicon dots is set to 250° C. or higher but 400° C. or lower; and the gas pressure in the plasma producing chamber during the formation of silicon dots is set to 0.27 Pa or higher but lower than 2.0 Pa, whereby silicon dots having a particle diameter of 5 nm or larger (e.g., about 10 nm for large-diameter silicon dots) can be formed.

When the time for exposing the substrate to hydrogen plasma in the pretreatment during this formation of silicon dots is too short, the effect of the plasma process is eliminated. On the other hand, if the time is too long, the surface of the substrate (for example, when the surface is a SiO₂ film, the SiO₂ film) may be damaged. Therefore, in general, the exposure time can be, for example, in the range of 1 second to 30 seconds.

When the temperature of the substrate in forming silicon dots is lower than 250° C., diffusion of the radicals of deposition species on the substrate is decreased, and growth of the silicon dots is not promoted sufficiently. When the temperature is higher than 400° C., the substrate may be damaged by the heat, and also the heat load of the apparatus for forming silicon dots is undesirably increased. Therefore, the temperature may be set to 250° C. or higher but 400° C. or lower.

When the gas pressure in the plasma producing chamber during the formation of silicon dots is lower than 0.27 Pa, maintaining plasma is difficult. On the other hand, when the gas pressure is 2.0 Pa or higher, the amount of the radicals of deposition species which reach the substrate is lowered and the silicon dots do not grow sufficiently. Therefore, the gas pressure may be set to 0.27 Pa or higher but lower than 2.0 Pa.

In view of these findings, the present invention provides

a method for forming silicon dots comprising applying a high-frequency power to an antenna with reduced inductance placed within a plasma producing chamber to produce inductively coupled plasma from a gas for forming silicon dots provided in the chamber, and forming silicon dots on a substrate disposed within the chamber in the presence of the inductively coupled plasma, the method for forming silicon dots comprising controlling, depending on particle diameter of silicon dots to be formed, conditions for a pretreatment of the substrate prior to formation of silicon dots, temperature of the substrate in forming silicon dots, and gas pressure in the plasma producing chamber during the formation of silicon dots to form silicon dots.

In this method for forming silicon dots according to the present invention,

(1) the pretreatment of the substrate is conducted by exposing the substrate to oxygen plasma,

the temperature of the substrate in forming silicon dots is set at room temperature (about 25° C.) or higher but lower than 250° C., the gas pressure in the plasma producing chamber during the formation of silicon dots is set to 2.0 Pa or higher but 6.0 Pa or lower to form silicon dots having a particle diameter smaller than 5 nm, or

(2) the pretreatment of the substrate is conducted by exposing the substrate to hydrogen plasma, the temperature of the substrate in forming silicon dots is set to 250° C. or higher but 400° C. or lower, and the gas pressure in the plasma producing chamber during the formation of silicon dots is set to 0.27 Pa or higher but lower than 2.0 Pa to form silicon dots having a particle diameter of 5 nm or larger.

Herein, the term “antenna with reduced inductance” means an antenna which has an inductance lower than a large antenna circling around the plasma producing region in the plasma producing chamber. This a relatively short antenna which is opposed to a plasma producing region in the plasma producing chamber, and has an end terminated without circling around the plasma producing region. Typical examples include a U-shaped antenna. The U-shaped antennas include, as well as literally U-shaped antennas, gate-shaped or square U-shaped antennas, semicircular and other arc-shaped antennas, and antennas in such shapes made up of arc-shaped portion and straight-line portions continuing thereto, among others.

The antenna with reduced inductance has an inductance L of, for example, about 200×10⁻⁹ [H] to 230×10⁻⁹ [H] or lower. When the frequency of high-frequency power input to the antenna is 13.56 MHz, impedance |Z| is about 45Ω or lower, and further about 18Ω to 20Ω or lower, for example.

An example of the formation of silicon dots (silicon nanoparticles) by the method for forming silicon dots according to the present invention is the case where a silane-based gas (for example, monosilane gas) and hydrogen gas are fed as gases for forming the silicon dots into the plasma producing chamber, and the inductively coupled plasma is produced from these gases.

It is desirable that the silicon dots are terminally treated with oxygen, nitrogen or other substances on their surfaces. The term “terminating treatment with oxygen, nitrogen or other substances” used herein means that oxygen or nitrogen is bound to the surfaces of the silicon dots so that (Si—O) bonds, (Si—N) bonds, or (Si—O—N) bonds are formed.

The oxygen bonds or nitrogen bonds formed by such terminating treatment can function to compensate a defect, e.g., uncombined dangling bond, on the surfaces of the terminally untreated silicon dots and can give a high-quality dot state in which the defect is substantially suppressed as a whole. When employed as electronic device materials, the silicon dots so terminally treated can achieve improvements in the properties required of the electronic devices. For example, when used as a TFT material, the silicon dots can improve the electron mobility in TFTs and can reduce OFF current. Moreover, the silicon dots can improve reliability, such as resistance to changes in the voltage-current characteristics even when used in TFTs for a long period of time.

To this end, in the method for forming silicon dots according to the present invention, the surfaces of the silicon dots may be terminally treated in plasma for terminating treatment produced by applying high-frequency power to a gas for terminating treatment selected from an oxygen-containing gas and a nitrogen-containing gas after the silicon dots are formed.

Examples of the oxygen-containing gas for terminating treatment include oxygen gas and nitrogen oxide (N₂O) gas. Examples of the nitrogen-containing gas include nitrogen gas and an ammonia (NH₄) gas.

This terminating treatment may be carried out in the plasma producing chamber, or the substrate on which the silicon dots are formed may be loaded into a terminally treating chamber which is in communication with the plasma producing chamber after the silicon dots are formed in the first plasma producing chamber, and may be subjected to the terminating treatment in the terminally treating chamber.

### EFFECT OF THE INVENTION

According to the present invention, a method for forming silicon dots which can form silicon dots at a relatively low temperature, with good controllability of the particle diameter of silicon dots depending on the particle diameter of silicon dots to be formed, can be provided.

### BRIEF DESCRIPTION OF THE DRAWINGS

FIG. 1 is a drawing showing an example of an apparatus which can be used for carrying out the method for forming silicon dots according to the present invention.

FIG. 2 is an explanatory drawing of shape, size and other properties of an antenna.

FIG. 3A is a drawing which shows a shutter device in a closed state.

FIG. 3B is a drawing which shows the shutter device of FIG. 3A in an open state.

FIG. 3C is a drawing which shows another example of shutter device.

FIG. 4 is a block diagram which shows an example of a control circuit of the shutter device.

FIG. 5A is a drawing which shows a state of the silicon dots formed by Experimental Example 1-1, observed with a transmission microscope.

FIG. 5B is a drawing which shows a state of the silicon dots formed by Experimental Example 1-2, observed with a transmission microscope.

FIG. 6A is a drawing which shows a state of the silicon dots formed by Experimental Example 2-1, observed with a transmission microscope.

FIG. 6B is a drawing which shows a state of the silicon dots formed by Experimental Example 2-2, observed with a transmission microscope.

FIG. 6C is a drawing which shows a state of the silicon dots formed by Experimental Example 2-3, observed with a transmission microscope.

FIG. 7A is a drawing which shows a state of the silicon dots formed by Experimental Example 3-1, observed with a transmission microscope.

FIG. 7B is a drawing which shows a state of the silicon dots formed by Experimental Example 3-2, observed with a transmission microscope.

FIG. 8A is a drawing showing an example of a semiconductor device using silicon dots.

FIG. 8B is a drawing showing another example of semiconductor device using silicon dots other.

### DESCRIPTION OF THE SYMBOLS

A Apparatus for forming a substrate with silicon dots and an insulating film
1 Apparatus for forming silicon dots
11 First plasma producing chamber
111 Top wall
12 First antenna
13 Busbar
14 Matching box
15 High-frequency power source
16, 19 Substrate holder
161, 191 Heater
100 Substrate holder supporting base
17 Exhaust device
18 Plasma state grasping device
G1 Silane-based gas supply device
G2 Hydrogen gas supply device
10 Shutter device
s1, s2, s1′, s2′ Shutter blade
g1 to g4 Gear
M Motor
S Substrate
2 Apparatus for forming insulating film
21 Second plasma producing chamber
211 Top wall
22 First antenna
23 Busbar
24 Matching box
25 High-frequency power source
26 Substrate holder
261 Heater
28 Plasma state grasping device
G3 Silane-based gas supply device
G4 Oxygen gas supply device
20 Shutter device
3 Substrate transferring path
V1, V2 Gate valve
31 Substrate transferring robot
41, 42 Shutter device control unit
51, 52 Motor drive circuit

### BEST MODE FOR CARRYING OUT THE INVENTION

Embodiments of the present invention will be described below with reference to drawings.

FIG. 1 shows an apparatus A for forming a substrate with silicon dots and an insulating film comprising an apparatus 1 for forming silicon dots and an apparatus 2 for forming insulating film which also serves as a pretreatment device.

The apparatus 1 for forming silicon dots comprises a first plasma producing chamber 11, in which two antennas 12 are placed next to each other, and a substrate holder 16 for supporting a substrate S is provided below the antennas 12. The substrate holder 16 comprises a heater 161 which heats the substrate S supported thereby.

Each of the antennas 12 protrudes to the outside of the chamber through a top wall 111 of the plasma producing chamber 11 at its both ends. One end of the portion protruding to the outside of the chamber of each of these two antennas 12 is connected to a busbar 13, and the busbar 13 is connected to an output-variable high-frequency power source 15 via a matching box 14. The other end of the portion protruding to the outside of the chamber of each of the two antennas 12 is grounded. The details of the antennas 12 will be described later.

A gas supply device G1 for supplying a silane-based gas into the plasma producing chamber 11 is connected to the chamber, and a gas supply device G2 which supplies hydrogen gas into the plasma producing chamber 11 is connected to the chamber. Examples of usable silane-based gas include monosilane (SiH₄) gas and a disilane (Si₂H₆) gas.

In this example, these silane-based gas and hydrogen gas are gases for forming silicon dots, and the gas supply devices G1 and G2 constitute a first gas supply device which supplies the gases for forming silicon dots into the plasma producing chamber 11.

Moreover, an exhaust device 17 which exhausts a gas from the plasma producing chamber 11 to reduce the pressure inside the chamber is also connected to the chamber.

Furthermore, the plasma producing chamber 11 is provided with a plasma state grasping device 18 for grasping the state of inductively coupled plasma formed in the manner described later.

The apparatus 2 for forming insulating film comprises a second plasma producing chamber 21, in which two antennas 22 are placed next to each other, and a substrate holder 26 for supporting the to-be-processed substrate S is provided below the antennas 22. The substrate holder 26 comprises a heater 261 which heats the substrate S supported thereby.

The antennas 22 have the same shape and dimension as the antennas 12, and as the antennas 12, their both ends protrude to the outside of the plasma producing chamber 21 through a top wall 211 of the chamber 21.

One end of the portion protruding to the outside of the chamber of each of the antennas 22 is connected to a busbar 23, and the busbar 23 is connected an output-variable high-frequency power source 25 via a matching box 24. The other end of the portion protruding to the outside of the chamber of each of the antennas 22 is grounded. The details of the antennas 22 will be described later.

A gas supply device G3 for supplying a silane-based gas into the chamber is connected to the plasma producing chamber 21, and a gas supply device G4 which supplies oxygen gas or hydrogen gas into the plasma producing chamber 21 is also connected to the plasma producing chamber. Examples of usable silane-based gas include monosilane (SiH₄) gas and a disilane (Si₂H₆) gas.

In this example, these silane-based gas and oxygen gas are gases for forming a silicon oxide (SiO₂) film, which is an insulating film, and the gas supply devices G3 and G4 constitute the second gas supply device which supplies the gases for forming insulating film into the plasma producing chamber 21. The gas supply device G4 which can supply oxygen gas or hydrogen gas alternatively is also a supply device of a gas for pretreatment and a supply device of oxygen gas for terminating treatment described later.

An exhaust device 27 which exhausts a gas from the plasma producing chamber 21 to reduce the pressure inside the chamber is also connected to the plasma producing chamber 21.

Furthermore, the plasma producing chamber 21 is provided with a plasma state grasping device 28 for grasping the state of inductively coupled plasma formed in the manner described later.

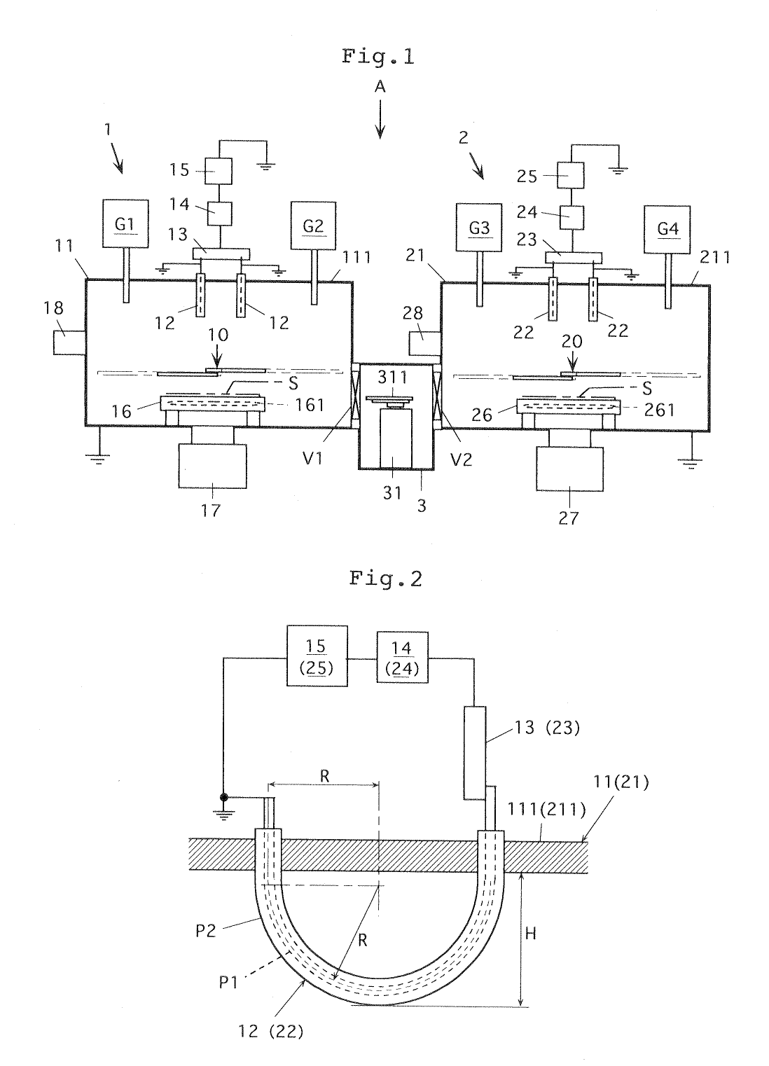

As shown in FIG. 2, each of the antennas 12 (22) is a copper pipe P1 having an outer diameter of ¼ inches (6.35 mm) and a wall thickness of about 1 mm covered with an insulating pipe P2 made of alumina having an outer diameter of 20 mm and a wall thickness of 3 mm, and has a shape made up of a semicircular portion (radius of curvature of the curved center line: R=50 mm) of the copper pipe P1 and straight line portions continuously connected to both ends of the semicircular portion.

The straight line portion of each of the antennas 12 (22) extends through the top wall 111 (211) of the plasma producing chamber 11 (21) in an airtight fashion.

A height H from the lower end of each of the antennas 12 (22) to the top wall 111 (211) in the plasma producing chamber 11 (21) 75 mm.

The interval of the two antennas 12 and the interval of the two antennas 22 in the plasma producing chambers are both 100 mm.

Each of the antennas 12 (22) has an inductance lower than a large antenna which circles around a plasma producing region in the plasma producing chamber. When the two antennas 12 (22) are used and placed next to each other as illustrated, the total inductance L of the two antennas is about 150×10⁻⁹ [H] to about 200×10⁻⁹[H], and when the frequency of the applied high-frequency power is 13.56 MHz, the total impedance |Z| of the two antennas is about 12Ω to about 18Ω. The higher the number of antennas, the lower the inductance and impedance.

The plasma state grasping devices 18, 28 have the same constitution. In this example, whether the plasma is in an unstable state or is stabilized can be grasped based on the spectral intensity of the light emitted from plasma.

Stated more specifically, in plasma, the gas decomposes and produces various kinds of atoms, ions, radicals and the like, as well as light emission. By spectroscopically analyzing the emitted light and grasping the type of spectral intensity which indicates that decomposition of the gas is not sufficiently proceeded or sufficiently proceeded, in other word, that the plasma is not stabilized yet or is stabilized, whether the plasma is in an unstable state or a stabilized state can be grasped.

Specific examples of the plasma state grasping device include a fiber optical spectroscope (model: USB2000, measurement targets: light-emitting atoms, light-emitting ions) manufactured by Ocean Optics, Inc., USA, and a 45° sector field high transmission ion energy analyzer/quadrupole mass analyzer (model: HAL EQP 500, measurement target: cations, anions, radicals, neutral particles) manufactured by Hiden Analytical Ltd, UK, among others.

In the plasma producing chamber 11, an openable and closable shutter device 10 which covers the to-be-processed substrate S supported on the substrate holder 16 from above to shield the substrate from plasma is further provided, and in the plasma producing chamber 21, the openable and closable shutter device 20 which can cover the to-be-processed substrate S supported on the substrate holder 26 from above to shield the substrate from the plasma is further provided.

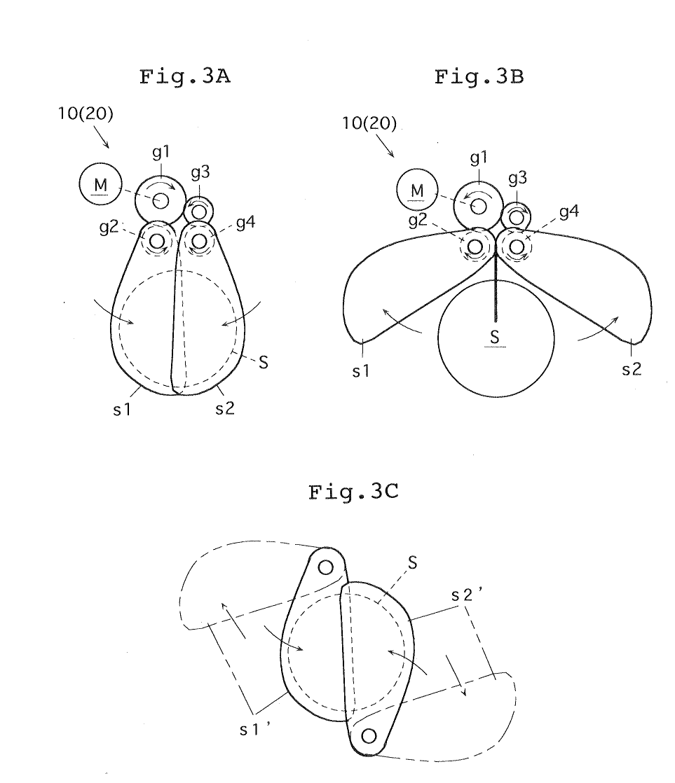

These shutter devices 10, 20 have the same constitution, and have a pair of shutter blades s1, s2, as shown in FIGS. 3A and 3B, in which one s1 of the shutter blades s1,s2, can be opened and closed by a motor M via gear trains g1 and g2, and the other shutter blade s2 can be opened and closed by the motor M via gear trains g1, g3 and g4.

As shown in FIG. 3A, the shutter blades s1, s2 are closed by being moved towards each other, whereby the substrate S on the substrate holder 16 (26) is shielded from the plasma, and as shown in FIG. 3B, the shutter blades s1, s2 are opened by being moved away from each other, whereby the substrate S on the substrate holder 16 (26) can be exposed to the plasma.

The shutter device is not limited to that mentioned above. For example, as shown in FIG. 3C, it may have such a structure that has shutter blades s1′, s2′ which can be opened and closed around the axis on both outer sides of the substrate S in the diametrical direction of the substrate S.

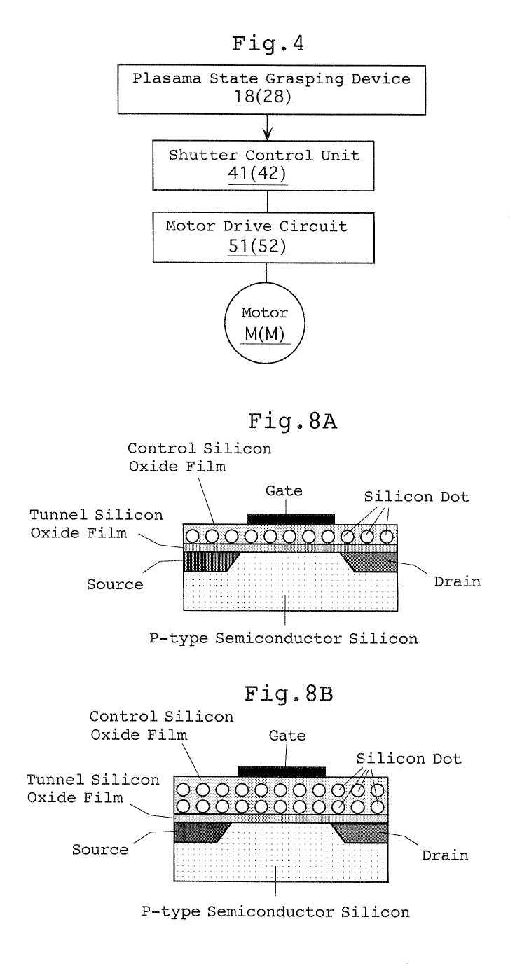

The shutter device 10 in the apparatus 1 for forming silicon dots is provided with a shutter control unit 41 as shown in FIG. 4, and while the information that the plasma formed in the plasma producing chamber 11 is in an unstable state is transmitted from the plasma state grasping device 18 to the control unit 41, the control unit 41 instructs the motor drive circuit 51 to keep the shutter blades s1, s2 closed, and when the information that the plasma is stabilized is transmitted from the plasma state grasping device 18 to the control unit 41, the control unit 41 instructs the motor drive circuit 51 to open the shutter blades s1, s2.

The shutter device 20 in the apparatus 2 for forming insulating film is also provided with a shutter control unit 42. While the information that the plasma formed in the plasma producing chamber 12 is in an unstable state is transmitted from the plasma state grasping device 28 to the control unit 42, the control unit 42 instructs the motor drive circuit 52 to keep the shutter blades s1, s2 closed, and when the information that the plasma is stabilized is transmitted from the plasma state grasping device 28 to the control unit 42, the control unit 42 instructs the motor drive circuit 52 to open the shutter blades s1, s2.

The plasma producing chamber 11 of the apparatus 1 for forming silicon dots and the plasma producing chamber 21 of the apparatus 2 for forming insulating film are communicated by the substrate transferring path 3 in an airtight fashion with respect to an ambient air. An openable and closable gate valve V1 which can shut off the chamber 11 from the path 3 in an airtight fashion is provided between the path 3 and the chamber 11, and an openable and closable gate valve V2 which can shut off the chamber 21 from the path 3 in an airtight fashion is provided between the path 3 and the chamber 21.

A substrate transferring robot 31 is placed inside the path 3. The robot 31 comprises a substrate transferring arm 311 which is capable of elevating, descending, pivoting, extending and retracting. The substrate S supported on the substrate holder 16 in the chamber 11 can be disposed on the substrate holder 26 in the chamber 21, or the substrate S supported on the substrate holder 26 in the chamber 21 can be disposed on the substrate holder 16 in the chamber 11 by the robot 31. As such a substrate transferring robot, a commercially available substrate transferring robot can be utilized. The robot 31 can also transfer the substrate to the outside or the inside of the path when a gate valve, which is not illustrated, is opened.

A substrate with silicon dots or a substrate with silicon dots and insulating film, which can be utilized for forming a semiconductor device having a MOS capacitor, a semiconductor device having a MOSFET structure and the like shown in FIGS. 8A and 8B can be provided by using the apparatus A described above. To begin with, the substrate S is set on the holder 26 within the plasma producing chamber 21 via the substrate transferring path 3 and by the robot 31, and the substrate S is heated to a predetermined pretreatment temperature by the holder heater 261 to subject the substrate to a pretreatment with plasma.

At this time, when the particle diameter of the silicon dots to be formed is smaller than 5 nm, a predetermined amount of oxygen gas is fed into the chamber 21 from the gas supply device G4 and at the same time the gas pressure in the chamber 21 is set to a predetermined value for the pretreatment by feeding the gas and by the exhaust device 27 so that the oxygen gas is converted into plasma and the substrate is exposed to the oxygen gas plasma for 1 second to 60 seconds, thereby conducting a pretreatment.

When the particle diameter of the silicon dots to be formed is 5 nm or larger, hydrogen gas is fed into the plasma producing chamber from the gas supply device G4 to convert the hydrogen gas into plasma, and the substrate is exposed to the hydrogen gas plasma for 1 second to 30 seconds to conduct a pretreatment.

Subsequently, the thus-pretreated substrate S is set on the holder 16 within the plasma producing chamber 11 of the apparatus 1 for forming silicon dots by the robot 31 at the substrate transferring path 3. The substrate is maintained at the silicon dot formation temperature by the holder heater 161, and the silane-based gas and hydrogen gas are introduced into the chamber 11 from the gas supply devices G1, G2 by predetermined amounts, and the inside of the chamber 11 is set to the silicon dot formation pressure by feeding the gases and by the exhaust of the exhaust device 17.

At this time, when the particle diameter of the silicon dots to be formed is smaller than 5 nm,

the temperature of the substrate in forming silicon dots is set at room temperature (about 25° C.) or higher but lower than 250° C. and the gas pressure in the plasma producing chamber during the formation of silicon dots is set to 2.0 Pa or higher but 6.0 Pa or lower, whereby silicon dots having a particle diameter smaller than 5 nm (e.g., about 1 nm for small-diameter silicon dots) are formed.

When the particle diameter of the silicon dots to be formed is 5 nm or larger,

the silicon dots having a particle diameter of 5 nm or larger (e.g., about 10 nm for large-diameter silicon dots) are formed by setting the temperature of the substrate in forming silicon dots to 250° C. or higher but 400° C. or lower, and the gas pressure in the plasma producing chamber during the formation of silicon dots to 0.27 Pa or higher but lower than 2.0 Pa.

Herein, the temperature of the substrate (affects the likelihood of diffusion of deposition species radicals SiHₓ) the gas pressure for forming silicon dots (affects the amount generated of SiHₓ radicals serving as a material of the silicon dots) and the pretreatment conditions of the substrate (affects the amount of SiOH bonds corresponding to the pretreatment of the substrate) are conditions which affect the degree that SiHₓ radicals accumulated on the substrate which serve as a material of nanosilicon particles are coupled to each other, and are therefore conditions which affect the particle diameter of the silicon dots.

The amount of SiOH bonds on the substrate is increased by the pretreatment with hydrogen plasma, and an increase in the amount of SiOH bonds increases the particle diameter of the silicon dots. Moreover, the amount of SiOH bonds on the substrate is lowered by the pretreatment with oxygen plasma, and a decrease in the amount of SiOH bonds decreases the particle diameter of the silicon dots.

In the silicon dot formation by the apparatus A, a high-frequency power is applied to the antenna 12 with reduced inductance placed within the plasma producing chamber 11 to produce inductively coupled plasma from a gas for forming silicon dots provided in the chamber (herein, silane-based gas and hydrogen gas). Therefore, high-density plasma containing the radical species (SiHₓ) which serves as a material of the silicon dots at a high density can be formed. Since silicon dots are formed on a substrate in the presence of the high-density plasma, silicon dots can be formed at a relatively low temperature.

Accordingly, silicon dots having a particle diameter smaller than 5 nm or silicon dots having a particle diameter of 5 nm or larger can be formed at a relatively low temperature, while the particle diameter of the silicon dots is well controlled, depending on the particle diameter of silicon dots to be formed.

Below is the description of Experimental Examples 1-1 and 1-2 in which a substrate with silicon dots and an insulating film (or insulating films) which can be utilized for forming semiconductor devices and the like shown in FIGS. 8A and 8B as examples was formed and it was also confirmed that the particle diameter of the silicon dots formed can be controlled by controlling the pretreatment conditions of the substrate. The above-mentioned fiber optical spectroscope (model: USB2000) manufactured by Ocean Optics, Inc., USA was employed as the plasma state grasping devices 18, 28.

### Experimental Example 1-1

### Pretreated with Oxygen Gas Plasma

(1) To begin with, the substrate S having a tunnel silicon oxide film formed by subjecting the surface of a P-type semiconductor silicon substrate as the to-be-processed substrate S to a thermal oxidation treatment in advance was disposed on the substrate holder 26 in the plasma producing chamber 21 via the substrate transferring path 3 by the robot 31, and the substrate was heated to 220° C. by the heater 261.

Generally speaking, the thickness of the silicon oxide film is about 1 nm to 100 nm, but it was 1 nm in this Example.

(2) The chamber 21 was evacuated by the exhaust device 27 to reduce the pressure inside the chamber 21 to 2×10⁻⁴ Pa or lower. Oxygen gas (90 sccm) was then supplied into the chamber 21 as a gas for pretreatment.

(3) While the pressure inside the chamber 21 was maintained to the pretreatment pressure of 0.67 Pa (5 mTorr) by supplying the gas and by operating the exhaust device 27, high-frequency power at 13.56 MHz and 3 kW was applied to the antennas 22 in a state that the shutter device 20 was closed to cover the substrate S, so that formation of inductively coupled plasma from the gas was started.

(4) The state of the plasma was grasped by the plasma state grasping device 28. Since the device 28 grasped that the plasma was in an unstable state for some time from immediately after the ignition of the plasma, the shutter control unit 42 still kept the shutter device 20 closed.

(5) As the plasma was stabilized with the lapse of time from the ignition of the plasma, the shutter control unit 42 opened the shutter device 20 in response to the information from the device 28 that indicated the stabilized state of the plasma to expose the substrate S to the plasma for 10 seconds.

(6) Thereafter, the pretreated substrate S was disposed by the holder 16 of the apparatus 1 for forming silicon dots within the plasma producing chamber 11 via the substrate transferring path 3 by the robot 31, and the substrate was heated towards 200° C. by the holder heater 161.

(7) The chamber 11 was evacuated by the exhaust device 17 to reduce the pressure inside the chamber 11 to 2×10⁻⁴ Pa or lower. Thereafter, monosilane (SiH₄) gas (5.4 sccm) and hydrogen gas (81 sccm) were fed into the chamber 11.

(8) While the pressure inside the chamber 11 was maintained to a silicon dot formation pressure of 4 Pa (30 mTorr) by supplying the gases and by operating the exhaust device 17, high-frequency power at 13.56 MHz and 3 kW was applied to the antennas 12 in a state that the shutter device 10 was closed to cover the substrate S, so that formation of inductively coupled plasma from the gases was started.

(9) The state of the plasma was grasped by the plasma state grasping device 18. Since the apparatus 18 grasped that the plasma was in an unstable state for some time from immediately after the ignition of the plasma, the shutter control unit 41 still kept the shutter device 10 closed.

(10) As the plasma was stabilized with the lapse of time from the ignition of the plasma, the shutter control unit 41 opened the shutter device 10 in response to the information from the apparatus 18 that indicated the stabilized state of the plasma to expose the substrate S to the plasma. The temperature of the substrate was raised to 200° C. by this time at the latest. Accordingly, formation of the silicon dots on the substrate S was started.

(11) After the time required to form the silicon dots having a desired particle diameter elapsed, application of electric power to the antennas 12 was stopped, and the gas remaining in the chamber 11 was sufficiently exhausted by the exhaust device 17, thereby completing the formation of the silicon dots.

The thus-formed silicon dots were observed with a transmission electron microscope (TEM) as described later. By conducting the next step following the above formation of the silicon dots, the terminating treatment of the silicon dots and formation of the insulating film on the silicon dots were carried out.

(12) That is, following the above (11), the gate valves V1, V2 were opened, and the substrate S on which the silicon dots were formed was transferred from the chamber 11 into the plasma producing chamber 21 of the apparatus 2 for forming insulating film by the transferring robot 31, and was supported on the substrate holder 26. The gate valves V1, V2 were then closed.

(13) The substrate S on the substrate holder 26 was heated to 220° C. by the heater 261.

(14) The chamber 21 was evacuated by the exhaust device 27 to reduce the pressure inside the chamber 21 to 2×10⁻⁴ Pa or lower. Oxygen gas (90 sccm) was then supplied into the chamber 21.

(15) While the pressure inside the chamber 21 was maintained to a terminating treatment pressure of 0.67 Pa (5 mTorr) by supplying the gas and by operating the exhaust device 27, high-frequency power at 13.56 MHz and 3 kW was applied to the antennas 22 in a state that the shutter device 20 was closed to cover the substrate S so that formation of inductively coupled plasma from the gas was started.

(16) The state of the plasma was grasped by the plasma state grasping device 28. Since the device 28 grasped that the plasma was in an unstable state for some time from immediately after the ignition of the plasma, the shutter control unit 42 still kept the shutter device 20 closed.

(17) As the plasma was stabilized with the lapse of time from the ignition of the plasma, the shutter control unit 42 opened the shutter device 20 in response to the information from the device 28 that indicated the stabilized state of the plasma to expose the substrate S to the plasma. The temperature of the substrate was raised to 220° C. by this time at the latest. Accordingly, the terminating treatment of the silicon dots on the substrate S was started.

(18) After a lapse of predetermined time for the terminating treatment passed, application of electric power to the antennas 22 was stopped, and the pressure inside the chamber 21 was reduced to 2×10⁻⁴ Pa or lower by the exhaust device 27. Gases for forming an insulating film (SiH₄ gas: 25.4 sccm, oxygen gas: 90 sccm) were then supplied.

(19) While the gas pressure in the chamber 21 was adjusted to 0.67 Pa (5 mTorr) by feeding the gases and by operating the exhaust device 27, high-frequency power at 13.56 MHz and 1 kW was applied to the antennas 22 in a state that the shutter device 20 was closed to cover the substrate S so that formation of inductively coupled plasma from the gases was started.

(20) As the plasma was stabilized, the shutter device 20 was opened to expose the substrate S to the plasma, and formation of an insulating film (control silicon oxide film) on the silicon dots on the substrate S was started.

(21) After the time required to form the control silicon oxide film having a desired thickness elapsed, application of electric power to the antennas 22 was stopped, and the gas remaining in the chamber 21 was sufficiently exhausted by the exhaust device 27, thereby completing the formation of the insulating film.

Thus, a substrate shown in, for example, FIG. 8A, which can be utilized for forming a semiconductor device can be obtained.

For example, the substrate used for forming the semiconductor device having a two silicon dot layer structure shown in, for example, FIG. 8B, may be transferred to the plasma producing chamber 11 again after the control silicon oxide film was formed, as described above to form silicon dots, and then the substrate may be transferred to the plasma producing chamber 21 to form a silicon oxide film.

Otherwise, silicon dots and insulating films having a desired laminated layer state can be formed by causing the substrate to reciprocate between the plasma producing chambers 11 and 21.

### Experimental Example 1-2

### Pretreated with Hydrogen Gas Plasma

The pretreatment of the substrate was conducted by exposing the substrate to hydrogen plasma in place of the oxygen plasma in Experiment Example 1-1 for 10 seconds. Silicon dots were formed with the other conditions being the same as in Experimental Example 1-1. As in Experimental Example 1-1, the terminating treatment of the silicon dots and formation of the insulating film on the silicon dots could be conducted successively.

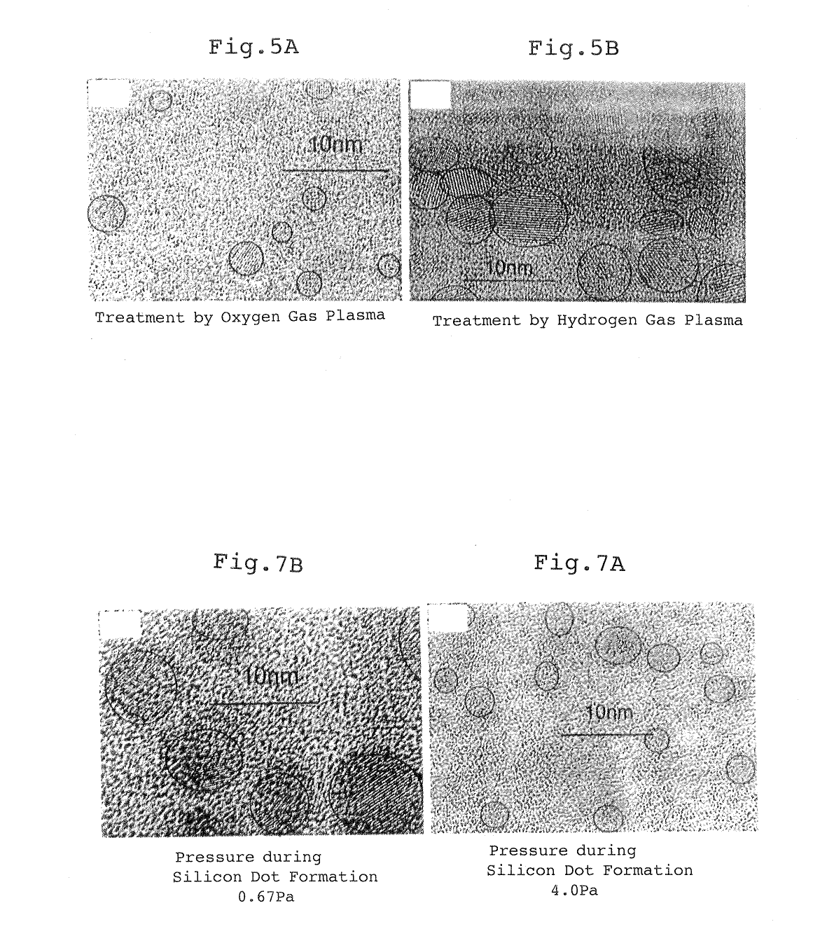

FIG. 5A shows an state (photograph) of the silicon dots formed on the substrate pretreated with the oxygen plasma of Experimental Example 1-1 observed by an transmission electron microscope (TEM), and FIG. 5B shows a state (photograph) of the silicon dots formed on the substrate pretreated with hydrogen plasma observed by the same microscope. It should be noted that the silicon dots are circled by lines in the photograph to facilitate understanding.

As can be seen from FIGS. 5A and 5B, when pretreatment process conditions are different, that is, when silicon dots are formed on the substrate pretreated with the oxygen plasma in this case, controlling the particle diameter of the silicon dots to smaller than 5 nm is made possible, and when the silicon dots are formed on the substrate pretreated with the hydrogen plasma, formation of the silicon dots having a particle diameter of 5 nm or larger is made possible. It is considered that the dots having a particle diameter smaller than 5 nm are formed even when the silicon dots are formed on the substrate pretreated with the hydrogen plasma, as shown in FIG. 5B, because the temperature of the substrate in forming silicon dots and the gas pressure in the chamber were 200° C. and 4 Pa (30 mTorr), respectively, which were suitable for silicon dots having a small particle diameter to be formed.

Below is the description of Experimental Examples 2-1, 2-2 and 2-3, in which the possibility of controlling the particle diameter of the silicon dots formed by controlling the temperature of the substrate in forming silicon dots by using the apparatus A was confirmed, and below is also the description of Experimental. Examples 3-1 and 3-2, in which the possibility of controlling the particle diameter of the silicon dots formed by controlling the gas pressure during the formation of the silicon dots was confirmed.

### Experimental Example 2-1

### No Pretreatment

Silicon dots were formed in the manner same as in Experimental Example 1-1 described above except that the pretreatment of the substrate was not carried out. As in Experimental Example 1-1, the terminating treatment of the silicon dots and formation of the insulating film on the silicon dots could be conducted successively.

In forming silicon dots in this experiment, the temperature of the substrate was 200° C., and the gas pressure was 4 Pa (30 mTorr).

### Experimental Example 2-2

### No Pretreatment

Silicon dots were formed in the manner same as in Experimental Example 1-1 except that the pretreatment of the substrate was not carried out and the temperature of the substrate in forming silicon dots was set to 300° C. Therefore, in forming silicon dots in this experiment, the temperature of the substrate was 300° C., and the gas pressure was 4 Pa (30 mTorr). As in Experimental Example 1-1, the terminating treatment of the silicon dots and formation of the insulating film on the silicon dots could be conducted successively.

### Experimental Example 2-3

### No Pretreatment

Silicon dots were formed in the manner same as in Experimental Example 1-1 except that the pretreatment of the substrate was not carried out and the temperature of the substrate in forming silicon dots was set to room temperature of 25° C. Therefore, in forming silicon dots in this experiment, the temperature of the substrate was 25° C. and the gas pressure was 4 Pa (30 mTorr). As in Experimental Example 1-1, the terminating treatment of the silicon dots and formation of the insulating film on the silicon dots could be conducted successively.

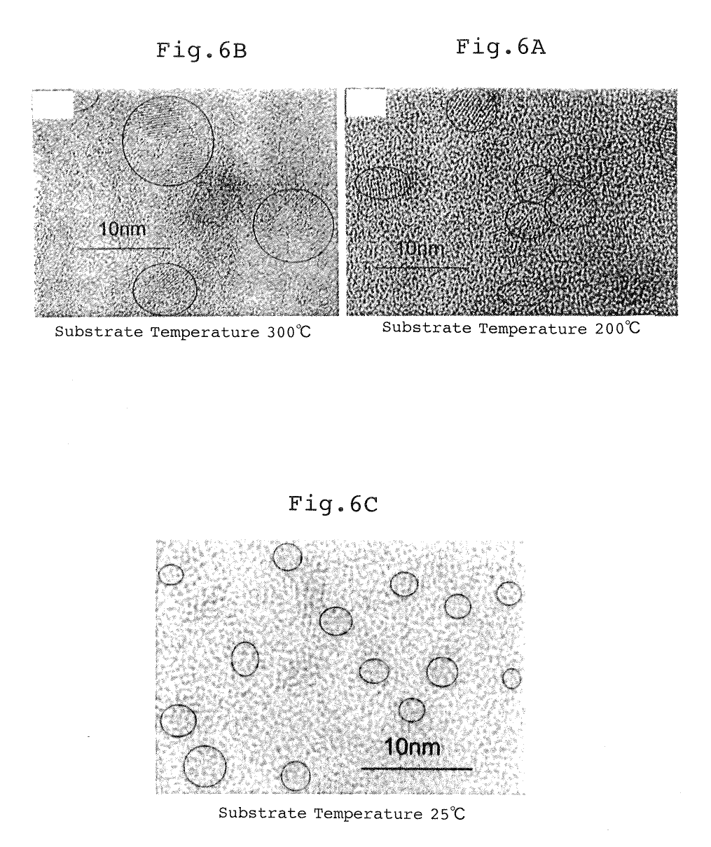

FIG. 6A shows a state (photograph) observed with a transmission electron microscope (TEM) of the silicon dots formed on the substrate in Experimental Example 2-1, and FIG. 6B shows a state (photograph) of the silicon dots formed on the substrate in Experimental Example 2-2 observed by the same microscope. FIG. 6C shows a state (photograph) of the silicon dots formed on the substrate in Experimental Example 2-3 observed by the same microscope. It should be noted that the silicon dots are circled by lines in the photograph to facilitate understanding.

As can be seen from FIGS. 6A, 6B and 6C, when the temperature of the substrate is set to a low value, formation of the silicon dots having a particle diameter smaller than 5 nm is made possible (refer to FIGS. 6A and 6C), while when the temperature of the substrate is set to a high value, formation of the silicon dots having a particle diameter of 5 nm or larger is made possible.

The reason why the dots having a particle diameter smaller than 5 nm are formed even when the temperature of the substrate was set to 300° C., as shown in FIG. 6B, is presumably because the gas pressure in the chamber during the formation of the silicon dots was 4 Pa (30 mTorr), which were suitable for silicon dots having a small particle diameter to be formed.

### Experimental Example 3-1

### No Pretreatment

Silicon dots were formed in the manner same as in Experimental Example 1-1 described above except that the pretreatment of the substrate was not carried out. In forming silicon dots in this experiment, the temperature of the substrate was 200° C., and the gas pressure was 4 Pa (30 mTorr). As in Experimental Example 1-1, the terminating treatment of the silicon dots and formation of the insulating film on the silicon dots could be conducted successively.

### Experimental Example 3-2

### No Pretreatment

Silicon dots were formed in the manner same as in Experimental Example 1-1 except that no pretreatment of the substrate was conducted and the gas pressure during the formation of the silicon dots was set to 0.67 Pa. Therefore, in forming silicon dots in this experiment, the temperature of the substrate was 200° C. and the gas pressure was 0.67 Pa. As in Experimental Example 1-1, the terminating treatment of the silicon dots and formation of the insulating film on the silicon dots could be conducted successively.

FIG. 7A shows a state (photograph) of the silicon dots formed on the substrate in Experimental Example 3-1 observed with a transmission electron microscope (TEM), and FIG. 7B shows a state (photograph) of the silicon dots formed on the substrate in Experimental Example 3-2 observed by the same microscope.

As can be seen from FIGS. 7A and 7B, when the gas pressure during the formation of the silicon dots is set to a high value, formation of the silicon dots having a particle diameter smaller than 5 nm is made possible (refer to FIG. 7A), while when the gas pressure is set to a low value, formation of the silicon dots having a particle diameter of 5 nm or larger is made possible (refer to FIG. 7B).

The reason why dots possibly having a particle diameter smaller than 5 nm are formed when the gas pressure is set as low as 0.67 Pa, as shown in FIG. 7B, is presumably because the temperature of the substrate during the formation of the silicon dots was 200° C., which is suitable for silicon dots having a small particle diameter to be formed.

### INDUSTRIAL APPLICABILITY

The present invention can be utilized for forming minute-size silicon dots used as electronic device materials, light emission materials and the like.

1. A method for forming silicon dots comprising applying high-frequency power to an antenna with low inductance placed in a plasma producing chamber to generate inductively coupled plasma from a gas for forming silicon dots supplied into the chamber; forming silicon dots on a substrate disposed inside the chamber in the presence of the inductively coupled plasma,
the method for forming silicon dots comprising controlling, depending on particle diameter of silicon dots to be formed, conditions for a pretreatment of the substrate prior to formation of silicon dots, temperature of the substrate in forming silicon dots and gas pressure in the plasma producing chamber during the formation of silicon dots, wherein
(1) the pretreatment of the substrate is carried out by exposing the substrate to oxygen plasma; the temperature of the substrate in forming silicon dots is set to not lower than room temperature but lower than 250° C.; and the gas pressure in the plasma producing chamber during the formation of silicon dots is set to 2.0 Pa or higher but 6.0 Pa or lower to form silicon dots having a particle diameter smaller than 5 nm, or
(2) the pretreatment of the substrate is conducted by exposing the substrate to hydrogen plasma; the temperature of the substrate in forming silicon dots is set to 250° C. or higher but 400° C. or lower; and
the gas pressure in the plasma producing chamber during the formation of silicon dots is set to 0.27 Pa or higher but lower than 2.0 Pa to form silicon dots having a particle diameter of 5 nm or larger.

2. A method for forming silicon dots according to claim 1, wherein in the formation of silicon dots, a silane-based gas and hydrogen gas are supplied as gases for forming the silicon dots into the plasma producing chamber, and the inductively coupled plasma is produced from these gases.

3. A method for forming silicon dots according to claim 1, wherein after the formation of the silicon dots, the surfaces of the silicon dots are subjected to a terminating treatment in the presence of plasma for terminating treatment produced by applying high-frequency power to at least one gas for terminating treatment selected from oxygen-containing gas and nitrogen-containing gas.

4. A method for forming silicon dots according to claim 2, wherein after the formation of the silicon dots, the surfaces of the silicon dots are subjected to a terminating treatment in the presence of plasma for terminating treatment produced by applying high-frequency power to at least one gas for terminating treatment selected from oxygen-containing gas and nitrogen-containing gas.
